(19) United States
(12) Patent Application Publication
(10) Pub. No.: US 2005/0231708 A1
(43) Pub. Date: Oct. 20, 2005

(54) Plate exposing apparatus

(75) Inventors: Hiroshi Sunagawa, Kanagawa (JP); Hiroshi Matsuoka, Kanagawa (JP); Yoshinori Katoh, Kanagawa (JP); Takeshi Kiso, Kanagawa (JP); Akinori Kimura, Kanagawa (JP); Ichirou Miyagawa, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD

(21) Appl. No.: 11/093,189

(22) Filed: Mar. 30, 2005

(30) Foreign Application Priority Data
Mar. 30, 2004 (JP) 2004-097650

(51) Int. Cl. G03F 7/00

(52) U.S. Cl. 355/85

(57) ABSTRACT

The plate exposing apparatus includes an exposing unit for exposing to light an original plate of a printing plate that does not have an oxygen barrier layer, on which latent image is formed by photo-polymerization based on exposure and which is subjected to alkali development, an oxygen interrupting unit for ensuring that the exposure is performed such that at least an exposed area of the original plate being exposed to light are substantially deprived of oxygen at least during the exposure and an oxygen blocking time control unit for controlling a period of time for which oxygen is interrupted by the oxygen interrupting unit.

### BACKGROUND OF THE INVENTION

This invention relates to a plate exposing apparatus, in particular, to a plate exposing apparatus that directly performs image recording on a original or virgin plate of a printing plate such as a presensitized (PS) plate by exposure to laser beam to make the printing plate such as a lithographic printing plate.

Conventionally, there has been known a method in which a presensitized plate (hereinafter, simply referred to as “PS plate”) having a photopolymerizable layer on a hydrophilic support is exposed and the nonimage areas are dissolved away with a developer solution to make a printing plate such as a lithographic printing plate. An exemplary photopolymerizable composition suitable for making negative-working lithographic printing plates is disclosed in JP 46-32714 B and its basic formula comprises a resin, a monomer or monomers, and an initiator.

With the recent advances in the technologies of laser beam exposure and data processing, direct platemaking, or a method that modulates a laser beam with image data and uses the modulated laser beam to directly record an image on a PS plate, is becoming a common practice. Since the PS plate for direct platemaking requires high sensitivity, it is also a common practice to use PS plates having a layer of the above-mentioned photopolymerizable composition formed thereon.

From a sensitivity viewpoint, it is preferred that the photopolymerizable layer uses a composition which comprises at least a compound having ethylenically unsaturated bonds and a photo-radical polymerization initiator. However, as is well known, radical polymerization reaction is greatly inhibited by oxygen and in actual use of the photopolymerizable layer, it has been required that an oxygen interrupting layer (oxygen barrier layer) be provided on it in order to maintain its sensitivity.

The oxygen barrier layer is commonly used as a coating that is formed on the photopolymerizable layer by applying water-soluble resins such as celluloses, gelatins and poly(vinyl alcohol) and, on account of high oxygen barrier quality, poly(vinyl alcohol) has found particularly extensive use. However, as it turned out, the water-soluble resins that compose the oxygen barrier layer have the following problems.

The PS plate having the above-described conventional photopolymerizable layer formed on it is first subjected to image recording with laser and then developed with an aqueous alkaline developer solution. The first problem to be considered is that the water-soluble resins in the oxygen barrier layer have such low solubility that they will remain on the surface of the photopolymerizable layer in the image areas after development. An obvious consequence of this phenomenon is that ink receptivity decreases in the printing process, producing printed matter with very low sharpness.

The second problem is that the water-soluble resins in the oxygen barrier layer are liable to produce insoluble matter (sludge) within the developer solution. With such sludge in the developer solution, the filter installed in the processor accommodating it will clog prematurely and needs frequent changes; as a result, the operational efficiency is lowered and the running cost is increased.

A solution to these problems has been proposed in JP 9-197655 A. According to this proposal, a PS plate having a photopolymerizable layer formed on it is placed on a member having a plurality of suction holes in such a way that the support faces down, a transparent sheet larger than the PS plate is superposed on top of the light-sensitive layer, and the PS plate is subjected to imagewise exposure with air being displaced through the suction holes, and development is subsequently performed to make a lithographic printing plate.

This approach, however, has the problem of being cumbersome since prior to each exposure, the PS plate is covered with a larger transparent sheet, which must be removed upon completion of the exposure. In addition, the transparent sheet preferably allows for several times of use but in practice it is difficult to handle, so it is prone to scratches and other damage, requiring early changes and eventually leading to an increased running cost.

### SUMMARY OF THE INVENTION

The present invention has been accomplished under these circumstances and has as an object providing a plate exposing apparatus that can advantageously be applied to direct platemaking in that even a original plate of a printing plate such as a presensitized (PS) plate that has no oxygen barrier layer and which is to be processed by alkali development after forming a latent image by photopolymerization can be handled by simple operation without incurring any increase in the running cost.

This object of the present invention can be attained by a plate exposing apparatus for exposing a original plate of a printing plate such as a PS plate that does not have an oxygen barrier layer, on which latent image is formed by photopolymerization and which is subjected to alkali development, characterized by having an oxygen blocking means for ensuring that exposure is performed such that at least the areas being exposed are substantially deprived of oxygen at least during exposure and an oxygen blocking time control means for controlling the period of time for which oxygen is interrupted by the oxygen blocking means.

The oxygen blocking time control means is preferably capable of controlling oxygen interruption for any duration of time in the period between a specified time before and a specified time after the exposing of the PS plate.

The oxygen blocking means has preferably means for replacement with an inert gas of the air in the closed space formed by a transparent retainer member that retains the PS plate on the side where the light-sensitive layer is provided and by a press member that covers the support side of the PS plate and which can be moved to contact or depart from the transparent retainer member. Alternatively, the oxygen blocking means may preferably have means for displacing the air in the closed space formed by a transparent retainer member that retains the PS plate on the side where the light-sensitive layer is provided and by a press member that covers the support side of the PS plate and which can be moved to contact or depart from the transparent retainer member.

In the plate exposing apparatus of the invention, the transparent retainer member that retains the PS plate on the side where the light-sensitive layer is provided and the press member that covers the support side of the PS plate and which can be moved to contact or depart from the transparent retainer member may be combined and assembled for scanning on either a plane or the inner surface or the outer surface of a cylinder.

These and other features of the present invention will become apparent from the following description.

According to the present invention, there is provided the advantage of offering a plate exposing apparatus that can advantageously be applied to direct platemaking in that even a PS plate that has no oxygen barrier layer and which is to be processed by alkali development after forming a latent image by photopolymerization can be handled by simple operation without incurring any increase in the running cost.

By using the plate exposing apparatus of the invention, one can obtain the additional advantage that the lithographic printing plate that is made has safety under white light, so even if it is left in a lighted environment for an extended period of time after exposure, printing can be done without forming any unwanted image such as fogging.

### BRIEF DESCRIPTION OF THE DRAWINGS

FIGS. 1A and 1B are side views showing schematically a plate exposing apparatus according to an embodiment of the present invention;

FIG. 2 is a flow sheet showing the sequence of major steps in the method of making lithographic printing plates according to an example of the present invention;

FIG. 3 is a side view showing schematically a plate exposing apparatus according to another embodiment of the present invention;

FIGS. 4A and 4B are side views showing schematically a plate exposing apparatus according to still another embodiment of the present invention;

FIG. 5 is a side view showing schematically a plate exposing apparatus according to yet another embodiment of the present invention;

FIGS. 6A, 6B, 6C and 6D are sectional views showing schematically a plate exposing apparatus according to a further embodiment of the present invention;

FIG. 7A is a perspective view showing schematically a plate exposing apparatus according to a still further embodiment of the present invention; and

FIG. 7B is a longitudinal section of the same apparatus as shown in FIG. 7A.

### BEST MODES FOR CARRYING OUT THE INVENTION

The following description begins with a original plate of a printing plate such as a presensitized (PS) plate suitable for exposure by the plate exposing apparatus according to the present invention; then, the plate exposing apparatus according to the present invention will be described in detail.

A PS plate that can advantageously be used to make a printing plate such as a lithographic printing plate by a process comprising exposure with the plate exposing apparatus of the present invention and subsequent development may be exemplified by one of the following type which has a laser-sensitive recording layer on an aluminum support, with no oxygen-interrupting overcoat (OC) layer being provided on top of the laser-sensitive recording layer.

The assignee of the subject application previously filed Japanese Patent Application 203623/1998 on an invention entitled “Method of Making Lithographic Printing Plate” (see JP 2000-35673 A) and described below is the photopolymerizable PS plate proposed in that application as having preferred printing performance, except that the OC layer is omitted from it.

More specifically, the following description concerns the constituents of a photopolymerizable PS plate having a light-sensitive layer of a so-called “photopolymer” type. Photopolymerizable light-sensitive compositions (simply referred to as photopolymerizable compositions) that are suitable for use in the “photopolymer” type light-sensitive layer contain an addition polymerizable, ethylenically unsaturated bond containing compound, a photopolymerization initiator and a binder polymer as the essential ingredients, optionally containing various compounds such as a colorant, a plasticizer and a thermal polymerization inhibitor.

The ethylenically unsaturated bond containing compound which is to be contained in the photopolymerizable composition is a compound having ethylenically unsaturated bonds such that when the photopolymerizable composition is irradiated with active or actinic rays, it undergoes addition polymerization under the action of a photopolymerization initiator to crosslink and harden. The ethylenically unsaturated bond containing compound may appropriately be selected from among any compounds having at least one, preferably at least two, terminal ethylenically unsaturated bonds, and examples have a variety of chemical morphologies including monomers, prepolymers (i.e., dimmers, trimers, and oligomers), mixtures thereof, copolymers thereof, etc. Exemplary monomers include esters of unsaturated carboxylic acids (e.g. acrylic acid, methacrylic acid, itaconic acid, crotonic acid, isocrotonic acid and maleic acid) and aliphatic polyol compounds, and amides of unsaturated carboxylic acids and aliphatic polyamine compounds. Also advantageous are urethane-based addition polymerizable compounds.

Depending on the wavelength of the light source to be used, the photopolymerization initiator to be contained in the photopolymerizable composition may appropriately be selected from among various photopolymerization initiators, taken either individually or in combinations of two or more species (to make photo-initiator systems). Preferred photo-initiator systems are described in JP 2001-22079 A under paragraphs [0021]-[0023].

The binder polymer to be contained in the photopolymerizable composition not only functions as an agent for forming a film of the photopolymerizable composition; in view of the need to dissolve the light-sensitive layer in an alkali developer solution, the binder polymer must be an organic high-molecular weight compound that can dissolve or swell in aqueous alkalies. Useful binder polymers are described in JP 2001-22079 A under paragraphs [0036]-[0063].

The additives described in JP 2001-22079 A under paragraphs [0079]-[0088] (e.g. surfactants for providing improved coating characteristics) are preferably added to the photopolymerizable composition.

In another preferred embodiment, the light-sensitive layer may be provided with an adhesive layer as an undercoat which is of the type described in JP 2001-228608 A under paragraphs [0131]-[0165].

More specific examples are given below.

Aluminum supports may advantageously be used in the present invention as exemplified by metals based on dimensionally stable aluminum, with supports made of pure aluminum or aluminum alloys being preferred. More specifically, a suitable aluminum support may be selected from among pure aluminum plates, aluminum-based plates alloyed with very small amounts of dissimilar elements, as well as plastics and paper that are laminated or evaporated with pure aluminum or alloyed aluminum. Also advantageous for use are composite sheets which have aluminum sheets bound to a poly(ethylene terephthalate) film as described in JP 48-18327 B.

The main components of the photopolymerizable light-sensitive layer which is used in the present invention are the addition polymerizable, ethylenically double-bond containing compound, the photopolymerization initiator, the high polymer binder, etc., with various compounds such as a colorant, a plasticizer and a thermal polymerization inhibitor being optionally added. The addition polymerizable double-bond containing compound may appropriately be selected from among any compounds having at least one, preferably at least two, terminal ethylenically unsaturated bonds, and examples have a variety of chemical morphologies including monomers, prepolymers (i.e., dimmers, trimers, and oligomers), mixtures thereof, copolymers thereof, etc. Exemplary monomers and copolymers thereof include esters of unsaturated carboxylic acids (e.g. acrylic acid, methacrylic acid, itaconic acid, crotonic acid, isocrotonic acid and maleic acid) and aliphatic polyol compounds, and amides of unsaturated carboxylic acids and aliphatic polyamine compounds.

Speaking of the monomeric esters of aliphatic polyol compounds and unsaturated carboxylic acids, specific examples of acrylate esters are ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate, polyester acrylate oligomers, etc.

Specific examples of methacrylate esters are tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, bis[p-(methacryloxyethoxy)phenyl]dimethylmethane, etc.

Specific examples of itaconate esters are ethylene glycol diitaconate, propylene glycol diitaconate, 1,3-butanediol diitaconate, 1,4-butanediol diitaconate, tetramethylene glycol diitaconate, pentaerythritol diitaconate, sorbitol tetraitaconate, etc. Specific examples of crotonate esters are ethylene glycol dicrotonate, tetramethylene glycol dicrotonate, pentaerythritol dicrotonate, sorbitol tetradicrotonate, etc.

Specific examples of isocrotonate esters are ethylene glycol diisocrotonate, pentaerythritol diisocrotonate, sorbitol tetraisocrotonate, etc.

Specific examples of maleate esters are ethylene glycol dimaleate, triethylene glycol dimaleate, pentaerythritol dimaleate, sorbitol tetramaleate, etc.

The monomeric esters listed above may be used in admixture.

Specific examples of the monomeric amides of aliphatic polyamine compounds and unsaturated carboxylic acids are methylenebis-acrylamide, methylenebis-methacrylamide, 1,6-hexamethylenebis-acrylamide, 1,6-hexamethylenebis-methacrylamide, diethylenetriamine trisacrylamide, xylylenebis-acrylamide, xylylenebis-methacrylamide, etc.

Other examples include vinyl urethane compounds containing at least two polymerizable vinyl groups in the molecule which have a hydroxyl containing vinyl monomer of the following general formula (A) added to a polyisocyanate compound having at least two isocyanate groups in the molecule, as described in JP 48-41708 B:
CH₂═C(R⁵)COOCH₂CH(R⁶)OH (A)
(where R⁵ and R⁶ each represent H or CH₃).

Yet other suitable examples include polyfunctional acrylates and methacrylates such as urethane acrylates of the type as described in JP 51-37193 A, polyester acrylates of the type as described in JP 48-64183 A, JP 49-43191 B and JP 52-30490 B and epoxy acrylates of the type produced by reacting epoxy resins with (meth)acrylic acid. Further useful examples are the compounds that are introduced as photocurable monomers and oligomers in Journal of The Adhesion Society of Japan, Vol. 20, No. 7, pp. 300-308 (1984). These compounds may be used in amounts of 5-70% by weight (hereinafter, % by weight is abbreviated as %), preferably 10-50%, of the total sum of the ingredients.

Depending on the wavelength of the laser light source to be used (which varies from 360 nm to 450 nm), the photopolymerization initiator may appropriately be selected from among various photo-initiators that are known in the patent and non-patent literature and which may be taken either individually or in combinations of two or more species (to make photo-initiator systems). Effective examples include, but are not limited to, the following: benzyl, benzoin ether, acetophenone, benzyldialkylketals, alkyl-o-benzoylbenzoate, α-acyl oxime esters, acyl phosphine oxides, glyoxyesters, Michler's ketone, anthraquinone, thioxanthone, acridine, phenazine, acridone, benzophenone, triazine, oxathiazole, titanocene, coumarin, 3-ketocoumarin, alkylanthraquinones, camphorquinone, tetraalkylthiuram monodisulfides, tetra(alkylperoxycarbonyl)benzophenones, etc. These derivatives are used extensively.

Other examples are the photo-initiators or photo-initiator systems that are described in “Zokanzai (Sensitizers)” (ed. by K. Tokumaru and S. Ohkawara, Kodansha Ltd.), “Chemistry & Technology of UV & EB Formulation for Coatings, Inks & Paints”, Vol. 3 (K.K. Dietliker, SITA Technology Ltd.), and “Shigaisen koka sisutemu (UV Curing Systems)” (K. Kato, published by Research Technology Center). The photopolymerization initiators described above may be used in amounts of from 0.05 to 100 parts by weight, preferably from 0.1 to 70 parts by weight, more preferably from 0.2 to 50 parts by weight, for 100 parts by weight of the ethylenically unsaturated compound.

The photopolymerizable composition typically contains an organic high-molecular weight compound as the binder and any organic high-molecular weight compounds may be used as long as they are miscible with the photopolymerizable, ethylenically unsaturated compound. Preferably, those organic high-molecular weight compounds are chosen which can be dissolved or swollen in water or weakly alkaline solutions to enable water development or weak alkali development. A suitable organic high-molecular weight compound may be selected in accordance with its use which is not only as an agent for forming a film of the photopolymerizable composition but also as a developer in water development, weak alkali development or organic solvent development. For example, water development can be performed with water-soluble, organic high-molecular weight compounds. Examples of such organic high-molecular weight compounds include addition polymers having carboxylic acid groups at side chains, as described in JP 59-44615 A, JP 54-34327 B, JP 58-12577 B, JP 54-25957 B, JP 54-92723 A, JP 59-53836 A and JP 59-71048 A; specific examples are methacrylic acid copolymers, acrylic acid copolymers, itaconic acid copolymers, crotonic acid copolymers, maleic acid copolymers, and partially esterified maleic acid copolymers.

Similarly useful examples are acidic cellulose derivatives having carboxylic acid groups at side chains. Other useful examples are addition polymers having hydroxyl groups to which cyclic acid anhydrides are added. Particularly advantageous among those polymers are copolymers comprising benzyl(meth)acrylate/(meth)acrylic acid/other addition polymerizable vinyl monomer as an optional component and copolymers comprising allyl(meth)acrylate/(meth)acrylic acid/other additional polymerizable vinyl monomer as an optional component. Yet other useful water-soluble organic polymers are poly(vinylpyrrolidone), poly(ethylene oxide), etc. In order to produce stronger hardened films, alcohol-soluble polyamides, polyethers of 2,2-bis-(4-hydroxyphenyl)-propane and epichlorohydrin, etc. are also useful. These organic high-molecular weight compounds may be mixed in the overall composition in any desired amounts. However, if their content exceeds ⁹⁰ wt % r, the result is not preferred from such viewpoints as the strength of the image formed. The preferred range is from 30 wt % to 50 wt %. The weight ratio of the photopolymerizable, ethylenically unsaturated compound to the organic high-molecular weight compound is preferably in the range from 1/9 to 9/1, more preferably from 2/8 to 8/2, and most preferably from 3/7 to 7/3.

In the present invention, in order to prevent unwanted thermal polymerization of the polymerizable, ethylenically unsaturated compound during production or storage of the photosensitive composition, a thermal polymerization inhibitor is desirably added in a small amount in addition to the above-described basic ingredients, Suitable examples of the thermal polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and N-nitrosophenylhydroxylamine cerium(III) salt.

The thermal polymerization inhibitor is preferably added in amounts ranging from about 0.01% to about 5% of the total weight of the photosensitive composition.

If necessary, in order to prevent the retardation of polymerization by oxygen, higher fatty acids such as behenic acid or their derivatives such as behenic acid amide may be added to the photosensitive composition so that they will be localized on the surface of the light-sensitive layer in the process of drying an applied coating. The higher fatty acids or their derivatives are preferably added in amounts ranging from about 0.5% to about 10% of the total weight of the photosensitive composition.

Furthermore, colorants may be added for the specific purpose of imparting a color to the light-sensitive layer. Exemplary colorants include pigments such as phthalocyanine-based pigments, azo-based pigments, carbon black, titanium oxide, etc., as well as ethyl violet, crystal violet, azo dyes, anthraquinone-based dyes and cyanine-based dyes. The dyes or pigments are preferably added in amounts of from about 0.5% to about 5% of the total weight of the photosensitive composition. In addition, in order to improve the physical properties of the hardened film, additives such as inorganic fillers and plasticizers exemplified by dioctyl phthalate, dimethyl phthalate and tricresyl phosphate may be added. These additives are preferably added in amounts not exceeding 10% of the total weight of the photosensitive composition.

To coat the support with the photopolymerizable composition of the present invention, the latter may be dissolved in a variety of solvents to prepare coating solutions, which are then applied. Solvents that can be used include acetone, methyl ethyl ketone, cyclohexane, ethyl acetate, ethylene dichloride, tetrahydrofuran, toluene, ethylene glycol monomethyl ether, ethylene glycol monoethyl ether, ethylene glycol dimethyl ether, propylene glycol nonomethyl ether, propylene glycol monoethyl ether, acetylacetone, cyclohexanone, diacetone alcohol, ethylene glycol monomethyl ether acetate, ethylene glycol ethyl ether acetate, ethylene glycol monoisopropyl ether, ethylene glycol monobutyl ether acetate, 3-methoxypropanol, methoxymethoxyethanol, diethylene glycol monomethyl ether, diethylene glycol monoethyl ether, diethylene glycol dimethyl ether, diethylene glycol diethyl ether, propylene glycol monomethyl ether acetate, propylene glycol monoethyl ether acetate, 3-methoxypropyl acetate, N,N-dimethylformamide, dimethyl sulfoxide, γ-butyrolactone, methyl lactate, ethyl lactate, etc. These solvents are used either alone or in admixture. The concentration of the solids in the coating solution is suitably between 1% and 50% by weight.

The photopolymerizable composition in a PS plate that is advantageous for use on the plate exposing apparatus according to the present invention may have a surfactant added to it in order to ensure that the applied layer will have a surface of improved quality. The coverage of the photopolymerizable composition is suitably in the range from about 0.1 g/m² to about 10 g/m², preferably from 0.3 g/m² to 5 g/m², more preferably from 0.7 g/m² to 3 g/m², in terms of the weight after drying.

The PS plate thus prepared by applying the photopolymerizable composition is advantageous for use on the plate exposing apparatus according to the present invention and, as already mentioned, it has no OC layer. This is for circumventing the following two major troubles: the OC layer may remain on the surface of the image areas during development with an alkali developer solution; and the OC layer is liable to produce insoluble matter (sludge) which will contaminate the developer solution to require more frequent changes of the filter.

On the following pages, a plate exposing apparatus of the present invention is described in detail with reference to the preferred embodiments shown in the accompanying drawings.

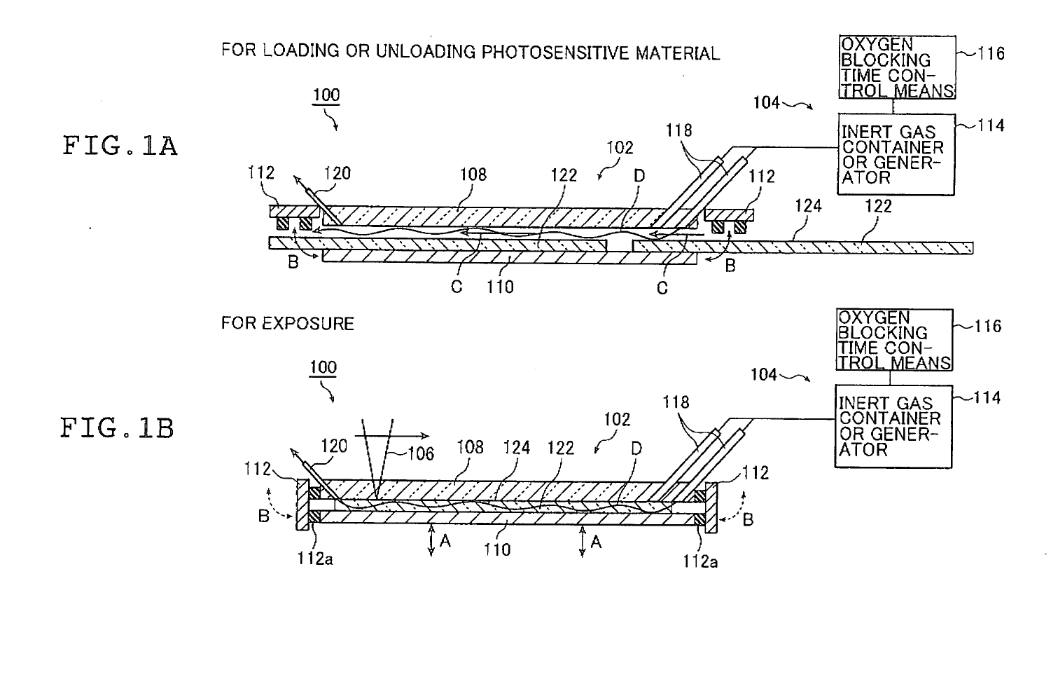

FIGS. 1A and 1B are side views showing schematically the essential part of the plate exposing apparatus according to an embodiment of the present invention.

The plate exposing apparatus according to the embodiment under consideration which is generally indicated by 100 mainly comprises a housing 102 for accommodating a original plate of a printing plate such as a PS plate (hereunder referred to as a photosensitive material), an oxygen-free state creating section 104 for replacing the air in the housing 102 with an inert gas, and a photosensitive material exposing means 106 for irradiating the photosensitive material 122 with a specified amount of exposing light.

The housing 102 comprises a transparent retainer member 108 as a flat plate typically made of glass, a press member 110 that is made of a rigid material and which is driven to reciprocate (in the directions of arrow A) by a moving mechanism (not shown) to be urged against and separated (brought out of engagement) from the transparent retainer member 108, and a wall member 112 that surrounds the peripheries of both members 108 and 110 and two sides of which pivot (in the directions of arrow B) to close and open the housing 102. The other two sides of the wall member 112 (which are parallel to the paper on which FIGS. 1A and 1B are drawn) are permanently fixed.

FIG. 1A shows the state where the wall member 112 has pivoted upward to separate from each of the transparent retainer member 108 and the press member 110 so that the photosensitive material 122 can be loaded into or unloaded from the housing 102; FIG. 1B shows the state where the wall member 112 has pivoted downward to come into contact with each of the transparent retainer member 108 and the press member 110, so the photosensitive material 122 can be exposed to light (in the housing 102 that has been closed).

The oxygen-free state creating section 104 comprises a container 114 of an inert gas such as nitrogen gas (or its generator but the term “container” is hereunder used for simplicity), an oxygen blocking time control means 116 for controlling the action of the inert gas container 114, a gas ejecting nozzle 118 through which the inert gas being supplied from its container 114 is introduced into the housing 102, and an exhaust nozzle 120 through which the gas is discharged out of the housing 102 after the end of exposure.

Speaking of the gas ejecting nozzle 118 through which to introduce the inert gas into the housing 102, special consideration is preferably made in order to ensure rapid replacement of the air in the housing 102 with the inert gas and an example is by arranging a plurality of such nozzles across the width of the photosensitive material (in the direction perpendicular to the paper on which FIGS. 1A and 1B are drawn). Speaking of the exhaust nozzle 120, it preferably has the minimum required cross-sectional area in order to prevent the loss of the inert gas to the outside of the housing 102 after it has replaced the air.

The photosensitive material exposing means 106 is an exposing device of a common, known scanning beam type which ensures that the photosensitive material 122 in the housing 102 is irradiated at the photosensitive layer 124 (the top surface of the photosensitive material 122 as seen in FIGS. 1A and 1B) with a specified amount of exposing light. In the case shown, the photosensitive layer 124 of the photosensitive material 122 as a flat plate is scanned two-dimensionally and exposed to a laser beam modulated in accordance with the data on the image to be recorded; it should, however, be noted that this is not the sole case of the present invention.

The plate exposing apparatus 100 according to the embodiment under consideration is operated in the following manner. First, the press member 110 is separated from the transparent retainer member 108 and the wall member 112 is pivoted to the OPEN position; then, the photosensitive material 122 to be exposed is loaded into the housing 102, the press member 110 is urged toward the transparent retainer member 108 and the wall member 112 is pivoted to the CLOSE position so that packings 112a seal the interior of the housing 102. Thereafter, according to a preset pattern of inert gas supply (for details, see below) and under control of the oxygen blocking time control means 116, an inert gas is supplied from the container 114 to replace the air in the housing 102.

When purging with the inert gas ends after the lapse of a specified period of time, the photosensitive material 122 in the housing 102 is subjected to specified scan beam exposure by the exposing means 106. In the embodiment under consideration, supply of the inert gas from the container 114 shall be continued during the exposure under control of the oxygen blocking time control means 116. When a specified period of time lapses after the end of exposure, the supply of the inert gas is discontinued, also under control of the oxygen blocking time control means 116, and thereafter the press member 110 is separated from the transparent retaining member 108 and the wall member 112 is pivoted to the OPEN position so that the interior of the housing 102 is reverted to normal air atmosphere.

Thus described above are the layout of the essential parts of the plate exposing apparatus 100 according to one embodiment of the present invention, as well as an outline of its operation.

On the following pages, the method for making a lithographic printing plate according to the present invention using the exposing apparatus 100 is described with reference to a specific example.

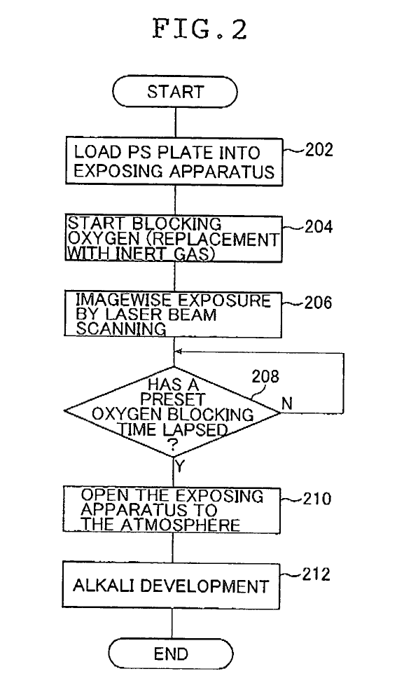

FIG. 2 is a flow sheet showing the sequence of major steps in the method for making lithographic printing plates using the exposing apparatus 100 according to the described embodiment of the present invention. As FIG. 2 shows, the method of interest for making a lithographic printing plate starts with separating the press member 110 from the transparent retainer member 108, pivoting the wall member 112 to the OPEN position, and loading the photosensitive material 122 to be exposed into the housing 102, with the photosensitive layer 124 facing up (step 202, in which the photosensitive material 122 is loaded in the direction indicated by arrow C in FIG. 1).

In the next step, the press member 110 is urged toward the transparent retainer member 108, the wall member 112 is pivoted to the CLOSE position, replacement of the air in the housing 102 by an inert gas is started (step 204, in which the inert gas is supplied in the direction indicated by D in FIG. 1). Every action in this step is performed under control of the oxygen blocking time control means 116.

To be more specific, the oxygen blocking time control means 116 has preset data for the oxygen blocking time both before and after the exposing of the photosensitive material 122 and on the basis of that data, replacement of the air in the housing 102 by an inert gas gets started.

When a preset specified period of time has passed since the start of replacement of the air in the housing 102 by an inert gas, it is considered that purging with the inert gas has substantially ended and the photosensitive material 122 (or, actually, the photosensitive layer 124) is subjected to specified scan beam exposure by the exposing means 106 (step 206). Needless to say, the exposure to be performed in step 206 is so-called “imagewise exposure” which is based on the image data for making lithographic printing plates.

After the exposure in step 206 ends, the inert gas supply from the container 114 is further continued on the basis of the data preliminarily set in the oxygen blocking time control means 116 for the oxygen blocking time that should continue after the end of exposure; at the point in time when the specified oxygen blocking time has passed (step 208), the inert gas supply from the container 114 is discontinued while at the same time the wall member 112 is pivoted to the OPEN position so that the interior of the housing 102 is opened to the atmosphere (step 210).

With the interior of the housing 102 being thusly opened to the atmosphere, the exposed photosensitive material 122 in the housing 102 is now in such a state that it permits the presence of oxygen in the photosensitive layer 124; it is substantially no longer photosensitive and can be handled in a lighted room. Hence, to perform development, the operator sets the exposed material 122 on a specified photosensitive material processor or a specified developing device (step 212).

In development step 212, development is performed with an aqueous alkaline development solution as is conventionally done and at that point in time the making of a lithographic printing plate ends.

According to the platemaking method that has been described above, direct platemaking can advantageously be applied in that even a PS plate that has no oxygen barrier layer and which is to be processed by alkali development after forming a latent image by photopolymerization can be handled by simple operation without incurring any increase in the running cost.

And, the plate exposing apparatus 100 described with reference to the foregoing embodiment can suitably be employed to implement the method.

The following is a modified version of the above-described method for making lithographic printing plates.

In the platemaking method described with reference to the above example, the action for interrupting oxygen is commenced at a point in time that precedes the start of exposure of the photosensitive material 122 by the duration of time required for the replacement of the air in the housing 102 with an inert gas to be substantially completed and even after the end of exposure, the replacement with the inert gas is continued for the period of time substantially equal to the time required for oxygen to permeate into the photosensitive layer 124 of the photosensitive materials 122. However, oxygen needs only to be purged from the photosensitive material 122 during its exposure, or the time during which there exist radicals generated in the photosensitive material for photopolymerization.

Therefore, the action for interrupting oxygen before the start of exposure or the action for interrupting oxygen after the end of exposure can each be omitted either partly or entirely. Needless to say, whether the action for such oxygen interruption should be omitted or not is preferably determined on the basis of the results of reviewing by detailed experimentation and other studies.

Further, in the above-described platemaking method, the action for interrupting oxygen is realized by replacing the air in the housing 102 with an inert gas. Of course, the same result can be obtained by removing substantially all of the air in the housing 102 (which actually is oxygen).

If desired, the action for interrupting oxygen may be performed in two steps, the first step by removing substantially all of the air in the housing 102 and the second step by introducing an inert gas after the air has been removed.

On the following pages, there are described several other embodiments of plate exposing apparatus that can be employed in place of the plate exposing apparatus 100.

Each of those alternatives is simple to handle, does not incur an increased running cost and, hence, provides a plate exposing apparatus that can be suitably applied in the direct platemaking process contemplated in the present invention.

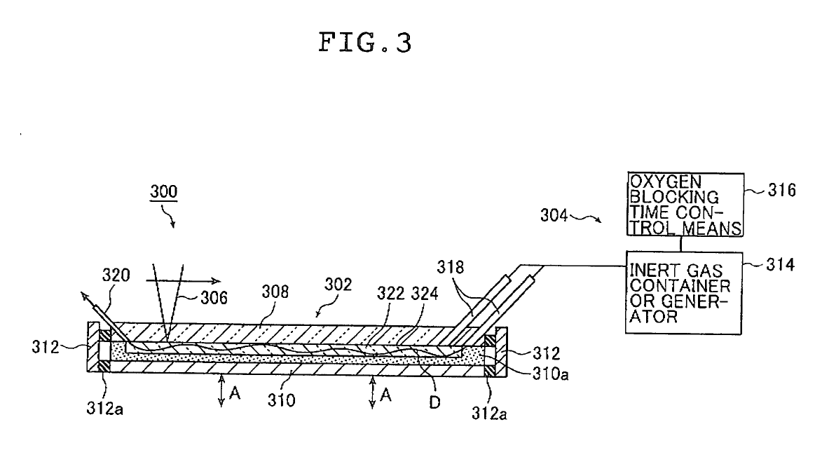

FIG. 3 is a side view showing schematically the essential parts of a plate exposing apparatus according to another embodiment of the present invention which is generally indicated by 300. The plate exposing apparatus 300 according to the embodiment under consideration may well be regarded as an improvement of the plate exposing apparatus 100 shown in FIGS. 1A and 1B. The difference is that the press member 310 of the housing 302 comprises a rigid base furnished with a cushion layer 310a made of a flexible material such as rubber or gel.

Having the cushion layer 310a in the press member 310, the plate exposing apparatus 300 according to the embodiment under consideration has the advantage that the volume of the gap that forms around the photosensitive material 322 when it is depressed by the press member 310 is sufficiently reduced to ensure that air can be removed or replaced with an inert gas more positively.

In FIG. 3, the components which are the same as those of the plate exposing apparatus 100 shown in FIGS. 1A and 1B are identified by the same reference numerals plus 200 and will not be described in detail.

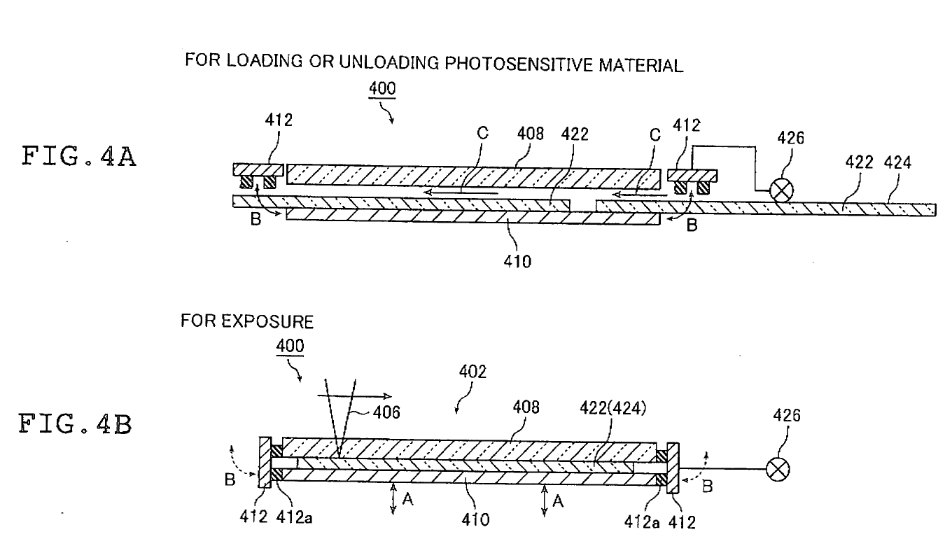

FIGS. 4A and 4B are side views showing schematically the essential parts of a plate exposing apparatus according to still another embodiment of the present invention which is generally indicated by 400. The plate exposing apparatus 400 according to the embodiment under consideration may well be regarded as a variant of the plate exposing apparatus 100 shown in FIGS. 1A and 1B. The difference is that the air in the housing 402 is not replaced with an inert gas but that substantially all of it is removed from the housing 402.

In the plate exposing apparatus 100 shown in FIGS. 1A and 1B, the oxygen-free state creating section 104 which essentially comprises the inert gas container 114 and the oxygen blocking time control means 116 which controls its action is used to replace the air in the housing 102 with an inert gas. In the plate exposing apparatus 400 according to the embodiment under consideration, the inert gas ejecting nozzle 418 is used as the port of evacuation effected by a vacuum pump 426.

Thanks to this design, the plate exposing apparatus 400 under consideration offers the advantage of enabling the formation of an oxygen-free atmosphere at relatively low cost by simply removing the air in the housing 402 rather than by replacing it with an inert gas.

In FIGS. 4A and 4B, the components which are the same as those of the plate exposing apparatus 100 shown in FIGS. 1A and 1B are identified by the same reference numerals plus 300 and will not be described in detail.

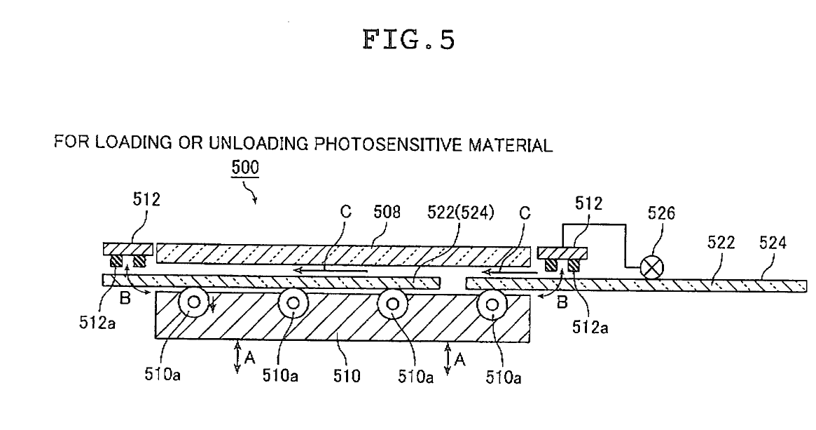

FIG. 5 is a side view showing schematically a variant of the plate exposing apparatus 400 according to the embodiment shown in FIGS. 4A and 4B. The plate exposing apparatus under consideration is generally indicated by 500 and characterized in that a press member 510 furnished with rollers 510a made of an elastic material such as rubber is used in place of the press member 400 of the plate exposing apparatus 400 shown in FIGS. 4A and 4B.

By virtue of this design, the plate exposing apparatus 500 according to the embodiment under consideration not only allows the photosensitive material 522 to be loaded into and unloaded from the housing 502 more smoothly but it also has the advantage that the press member 510 needs to be separated by a smaller distance from the photosensitive material 522 when it is loaded into or unloaded from the housing 502; this contributes to shortening the time required to change photosensitive materials.

In FIG. 5, the components which are the same as those of the plate exposing apparatus 400 shown in FIGS. 4A and 4B are identified by the same reference numerals plus 100 and will not be described in detail.

The foregoing examples relate to the plate exposing apparatus of a so-called “flat bed type” which sets the photosensitive material on a flat plate. On the pages that follow, examples of the so-called “drum type” exposing apparatus having a drum-shaped, photosensitive material retainer are described. As is well known, plate exposing apparatuses of the drum type comprise an inner drum type (exposing light is applied to the inner surface of the drum) and an outer drum type (exposing light is applied to the outer surface of the drum) and the following description covers both versions.

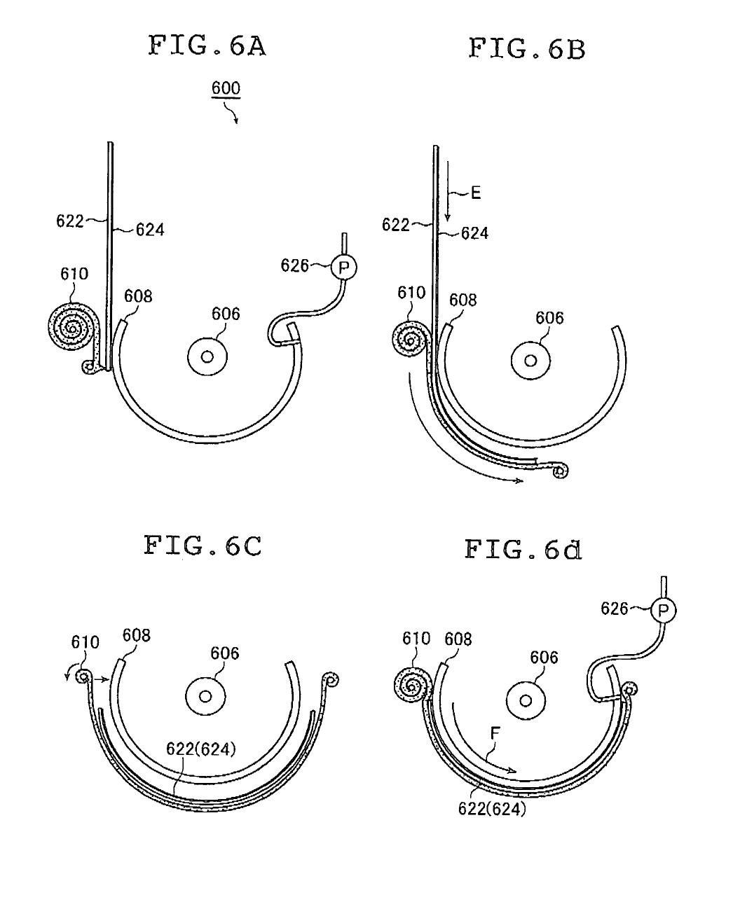

FIGS. 6A, 6B, 6C and 6D show a plate exposing apparatus of the inner drum type by means of sections of the drum-shaped, photosensitive material retainer that are cut through a plane crossing its center axis at right angles. The drum is yet to be loaded with the photosensitive material (FIG. 6A), it is being loaded with the photosensitive material (FIG. 6B), it is being prepared for evacuation after loading the photosensitive material (FIG. 6C), and it is in the process of evacuation (FIG. 6D).

The plate exposing apparatus according to the embodiment under consideration is generally indicated by 600 and comprises the following main components; a transparent retainer member 608 made of a glass cylinder part of which is taken away; a mechanism provided outside the transparent retainer member 608 for feeding and taking up a flexible press member 610; an exhaust mechanism (vacuum pump 626) for removing air out of a closed space (for details, see below) that is formed between the two members 608 and 610; and a laser beam scan exposing means 606 which is provided inside the transparent retainer member 608 and which uses a rotating mirror (spinner mirror).

The mechanism for feeding and taking up the press member 610 is so adapted that it can feed or take up the press member 610 at a desired position between its leading and trailing edges; it is also adapted to be capable of driving the press member 610 not only in the same direction but also in opposite directions. Because of this design, the mechanism for feeding and taking up the press member 610 first receives the photosensitive material 622 to be loaded, then transports it to a predetermined position, where it cooperates with the exhaust mechanism to retain the photosensitive material 622 within the closed space that it forms with the transparent retainer member 608.

In the plate exposing apparatus 600 according to the embodiment under consideration, the photosensitive material 622 that has been supplied, with the photosensitive layer 624 facing the transparent retainer member 608 (i.e., facing inward), is first received by driving the feed/take-up mechanism of the press member 610 in a clockwise direction (FIG. 6A) and then transported, as indicated by arrows E and F, to a specified position suitable for exposure by the scan exposing means 606 (FIGS. 6B, 6C and 6D), where the interior of the space (closed space) formed between the photosensitive material 622 and its transparent retainer member 608 is subjected to vacuum drawdown by the feed/take-up mechanism of the press member in cooperation with the exhaust mechanism.

After substantially all of the air that surrounds the photosensitive material 622 loaded to a specified position has been thusly removed, the scan exposing means 606 is actuated to perform common laser beam scan exposure on the photosensitive material 622. The aforementioned vacuum drawdown of the closed space (i.e., to keep its interior in an oxygen-free state) is preferably continued at least until exposure ends, more preferably until the passage of a specified period of time after the end of exposure.

A benefit this design offers to the plate exposing apparatus 600 according to the embodiment under consideration is that even if it employs the drum-shaped transparent retainer member 608, substantially all of the air in the housing 602 can be removed, ensuring that the photosensitive material 622 loaded into the housing 602 can be exposed more positively and easily in the oxygen-free environment.

In FIGS. 6A, 6B, 6C and 6D, the components which are the same as those of the plate exposing apparatus 100 shown in FIGS. 1A and 1B are identified by the same reference numerals plus 500 and will not be described in detail.

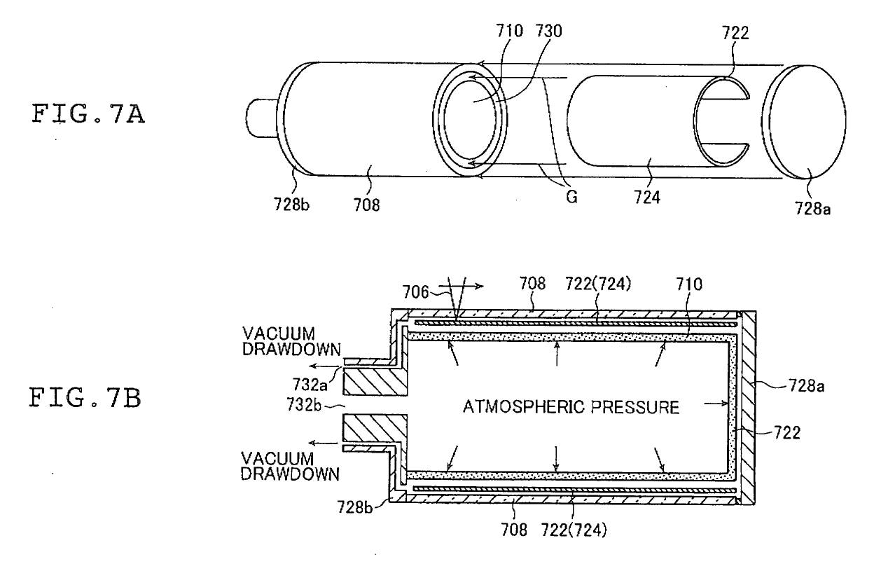

FIGS. 7A and 7B show an example of a plate exposing apparatus of the outer drum type; FIG. 7A is a section of the drum-shaped, photosensitive material retainer that is cut through a plane crossing its center axis at right angles; and FIG. 7B is a section of the retainer that is cut through a plane passing through its center axis. FIG. 7A is also a perspective view showing schematically the photosensitive material as it is being loaded into the housing, and FIG. 7B illustrates the photosensitive material as it is subjected to evacuation after loading.

The plate exposing apparatus according to the embodiment under consideration is generally indicated by 700 and comprises the following main components: a transparent retainer member 708 made of a glass cylinder; a cylindrical flexible press member 710 provided inside the transparent retainer member 708; an exhaust mechanism (having a vacuum pump not shown) for removing air out of a closed space (for details, see below) that is formed between the two members 708 and 710; and a laser beam scan exposing means 706 which is provided outside the transparent retainer member 708.

The two ends of the transparent retainer member 708 are closed with caps of closing members 728a and 728b. One of those closing members, say, member 728b, has a vent opening 732a through which to remove air from within a gap 730 in the form of a thin-walled cylinder that is formed between the transparent retainer member 708 and the press member 710; the vent opening 732a is connected to the vacuum pump referred to above. The closing member 728b also has a communication hole 732b for maintaining the pressure in the press member 710 atmospheric.

Designed this way, the plate exposing apparatus 700 according to the embodiment under consideration operates as follows: the photosensitive material 722 is loaded into the gap 730 (in the direction of arrow G) and the vacuum pump is actuated to remove air out of the gap 730 via the vent opening 732a, whereupon the press member 710, under the atmospheric pressure being exerted on its inner surfaces via the communication hole 732b, depresses the photosensitive material 722 toward the transparent retainer member 708 so that it is positively retained in position while at the same time the vacuum around it is also maintained positively.

When substantially all of the air that surrounds the photosensitive material 722 has been thusly removed, the scan exposing means 706 is actuated to perform laser beam scan exposure on the photosensitive material 722. The aforementioned vacuum drawdown of the closed space (i.e., the gap 730) (to create an oxygen-free state) is preferably continued at least until exposure ends, more preferably until the passage of a specified period of time after the end of exposure.

A benefit this design offers to the plate exposing apparatus 700 according to the embodiment under consideration is that even if it employs the drum-shaped transparent retainer member 708, substantially all of the air in the housing 702 can be removed, ensuring that the photosensitive material 722 loaded into the housing 702 can be exposed more positively and easily in the oxygen-free environment.

Note that the evacuation mechanism in the plate exposing apparatuses 600 and 700 according to the embodiments described above with reference to FIGS. 6 and 7 may be replaced by a mechanism for replacing the air in the housing 702 with an inert gas. Needless to say, this alternative design is essentially identical in other respects and can yet create an oxygen-free environment in a more positive way.

As described on the foregoing pages, the present invention provides a plate exposing apparatus that can advantageously be applied to direct platemaking in that even a PS plate that has no oxygen barrier layer and which is to be processed by alkali development after forming a latent image by photopolymerization can be handled by simple operation without incurring any increase in the running cost.

The foregoing embodiments are merely intended to be exemplary of the present invention and it goes without saying that the present invention is by no means limited to those embodiments and various modifications and improvements can be made without departing from the scope and spirit of the invention.

1. A plate exposing apparatus, comprising:
exposing means for exposing to light an original plate of a printing plate that does not have an oxygen barrier layer, on which latent image is formed by photo-polymerization based on exposure and which is subjected to alkali development;
oxygen blocking means for ensuring that the exposure is performed such that at least an exposed area of said original plate being exposed to light are substantially deprived of oxygen at least during the exposure; and
oxygen blocking time control means for controlling a period of time for which oxygen is interrupted by said oxygen blocking means.

2. The plate exposing apparatus according to claim 1, wherein said oxygen blocking time control means is capable of controlling oxygen interruption for any duration of time in the period between a first specified time before and a second specified time after the exposure of said original plate.

3. The plate exposing apparatus according to claim 1, wherein said oxygen blocking means comprises:
a transparent retainer member that retains said original plate on a first side where said image recording layer is provided;
a press member that covers a second side of said support of said original plate and which can be moved to contact or depart from said transparent retainer member; and
replacement means for replacing with an inert gas air in a closed space formed by said transparent retainer member and said press member.

4. The plate exposing apparatus according to claim 1, wherein said oxygen blocking means comprises:
a transparent retainer member that retains said original plate on a first side where said image recording layer is provided;
a press member that covers a second side of said support of said original plate and which can be moved to contact or depart from said transparent retainer member; and
displacement means for displacing air in a closed space formed by said transparent retainer member and said press member.

5. The apparatus according to claim 1, wherein said printing plate exposing apparatus is a flat bed type exposing apparatus for scanning on a plane of a flat bed, an inner drum type exposing apparatus for scanning on an inner surface of a drum or an outer drum type exposing apparatus for scanning on an outer surface of a drum.

6. The apparatus according to claim 3, wherein said transparent retainer member that retains said original plate on the first side where said image recording layer is provided and a press member that covers the second side of said support of said original plate and which can be moved to contact or depart from said transparent retainer member are combined and assembled for scanning on either a plane of a flat bed or an inner surface of a drum or an outer surface of a drum.

7. The apparatus according to claim 4, wherein said transparent retainer member that retains said original plate on the first side where said image recording layer is provided and a press member that covers the second side of said support of said original plate and which can be moved to contact or depart from said transparent retainer member are combined and assembled for scanning on either a plane of a flat bed or an inner surface of a drum or an outer surface of a drum.
